(19) United States
(12) Patent Application Publication
(10) Pub. No.: US 2007/0163716 A1
(43) Pub. Date: Jul. 19, 2007

(54) Gas distribution apparatuses and methods for controlling gas distribution apparatuses

(75) Inventors: Yi-Li Hsiao, Hsinchu City (TW); Chen-Hua Yu, Hsin-Chu (TW); Jean Wang, Hsin Chu (TW); Lawrance Sheu, Hsinchu City (TW)

Correspondence Address: DUANE MORRIS LLP;IP DEPARTMENT (TSMC), 30 SOUTH 17TH STREET, PHILADELPHIA, PA, 19103-4196, US

(73) Assignee: Taiwan Semiconductor Manufacturing Co., Ltd.

(21) Appl. No.: 11/335,455

(22) Filed: Jan. 19, 2006

(51) Int. Cl. H01L 21/306; C23F 1/00; C23C 16/00

(52) U.S. Cl. 156/345.26; 118/719; 156/345.34

(57) ABSTRACT

A gas distribution apparatus includes a first plate and a second plate comprising a plurality of first openings and second openings, respectively. The second plate is disposed in overlapping relation with the first plate. Overlaps of the first openings and the second openings form third openings, which provide a first gas distribution pattern at a first orientation of the plates relative to one another and a second gas distribution pattern at a second orientation different than the first orientation.

### BACKGROUND OF THE INVENTION

1. Field of the Invention

The present invention relates to gas distribution apparatuses and methods of controlling gas distribution apparatuses.

2. Description of the Related Art

With advances in electronic products, semiconductor technology has been widely applied in manufacturing memories, central processing units (CPUs), liquid crystal displays (LCDs), light emission diodes (LEDs), laser diodes and other devices or chip sets. In order to achieve high-integration and high-speed requirements, dimensions of semiconductor integrated circuits have been reduced, and various materials and techniques have been proposed to achieve these requirements and overcome obstacles during manufacturing. In addition, increases of wafer dimensions, such as to 12-inch wafers, make process uniformity more difficult and complex. For example, gas distributions provided within an etch chamber can substantially affect process uniformity of wafers. Thus, controlling the processing conditions for wafers within chambers or tanks has become essential.

FIG. 1A is a schematic drawing showing a prior art semiconductor processing apparatus, and FIG. 1B is a picture of a prior art shower head.

In FIG. 1A, a semiconductor processing apparatus 100 includes a chamber 105, a stage 110, a shower head 120, a power supply 130, a stage supporter 140 and a conduit 150. The stage 110 and the shower head 120 are disposed within the chamber 105. The stage supporter 140 is connected to, and supports, the stage 110. The shower head 120 is disposed over the stage 110. The conduit 150 is connected to the shower head 120 and provides a gas 170 to the chamber 105 by way of the openings 120a. The power supply 130 is coupled to the shower head 120 to ionize the gas 170 so as to generate plasma in the chamber 105.

FIG. 1B shows a picture of a portion of the shower head 120. The openings 120a are uniformly distributed on the shower head 120 in concentric rings spaced various distances from a center pint. The dimensions and number of the openings 120a determine the amount of gas distribution within the chamber 105. If a high gas amount at the edge of the shower head 120 is desired, more or larger openings 120a are configured at the edge of the shower head 120. In contrast, if a high gas amount at the center of the shower head 120 is desired, more or larger openings 120a are configured at the center of the shower head 120. In the prior art method, the shower head 120 is fixed to the chamber 105 to distribute the gas 170 provided by way of the conduit 150. If a different gas distribution is desired, a shower head 120 having a different dimension and distribution of the openings 120a is applied to the chamber 105. This prior art method is complex and inefficient for semiconductor manufacturing because the assembly or disassembly of the shower head 120 requires the semiconductor processing apparatus 100 to be shut down.

U.S. Pat. No. 4,792,378 provides a chemical vapor transport reactor gas dispersion disk for counteracting vapor pressure gradients to provide a uniform deposition of material films on a semiconductor slice. The disk has a number of apertures arranged so as to increase in aperture area per unit of disk area when extending from the center of the disk to its outer peripheral edge.

U.S. Patent Publication No. 2003/0136516 provides a gas diffusion plate. The gas diffusion plate supplies process gases into a chamber of an inductively coupled plasma (ICP) etcher. The gas diffusion plate includes a porous plate comprised of a plurality of balls and formed by compressing and curing the plurality of balls. The porous plate has a circular planar shape. A plurality of gas flow grooves are formed on an upper surface of the porous plate. A gas distribution plate has a plurality of gas-feed holes at the bottom thereof and a plurality of gas-feed passages in the side portion thereof. The gas distribution plate surrounds lower and side portions of the porous plate.

U.S. Patent Publication No. 2005/0223986 provides another gas distribution plate for distributing gas in a processing chamber. The distribution plate includes a diffuser plate having an upstream side and a downstream side, and a plurality of gas passages passing between the upstream and downstream sides of the diffuser plate. At least one of the gas passages has a right cylindrical shape for a portion of its length extending from the upstream side and a coaxial conical shape for the remainder length of the diffuser plate. The upstream end of the conical portion has substantially the same diameter as the right cylindrical portion. The downstream end of the conical portion has a larger diameter.

Improved gas distribution apparatuses and methods of controlling a gas distribution apparatus are desired.

### SUMMARY OF THE INVENTION

In accordance with some embodiments, an apparatus comprises a first plate and a second plate. The first plate comprises a plurality of first openings. The second plate is disposed in overlapping relation with the first plate and comprises a plurality of second openings. Overlaps of the first openings and the second openings form third openings. The third openings provide a first gas distribution pattern at a first orientation of the plates relative to one another and a second gas distribution pattern at a second orientation different than the first orientation.

The above and other features of the present invention will be better understood from the following detailed description of the preferred embodiments of the invention that is provided in connection with the accompanying drawings.

### BRIEF DESCRIPTION OF THE DRAWINGS

Following are brief descriptions of exemplary drawings. They are mere exemplary embodiments and the scope of the present invention should not be limited thereto.

FIG. 1A is a schematic drawing showing a prior art semiconductor processing apparatus, and FIG. 1B is a picture of a prior art shower head.

FIG. 2 is a cross-sectional view showing an exemplary processing apparatus.

FIGS. 3A and 3B are schematic drawings of exemplary plates.

FIGS. 4A and 4B are enlarged schematic drawings of portions of the plates of FIGS. 3A and 3B, respectively.

FIGS. 5A and 5B are schematic drawings showing overlaps of the partial plates of FIGS. 4A and 4B.

FIGS. 6A and 6B illustrate gas distributions along a radial direction of a wafer.

FIGS. 7A and 7B illustrate alternative gas distributions along a radial direction of a wafer.

FIGS. 7C and 7D are enlarged schematic drawings of portions of another embodiment of exemplary plates.

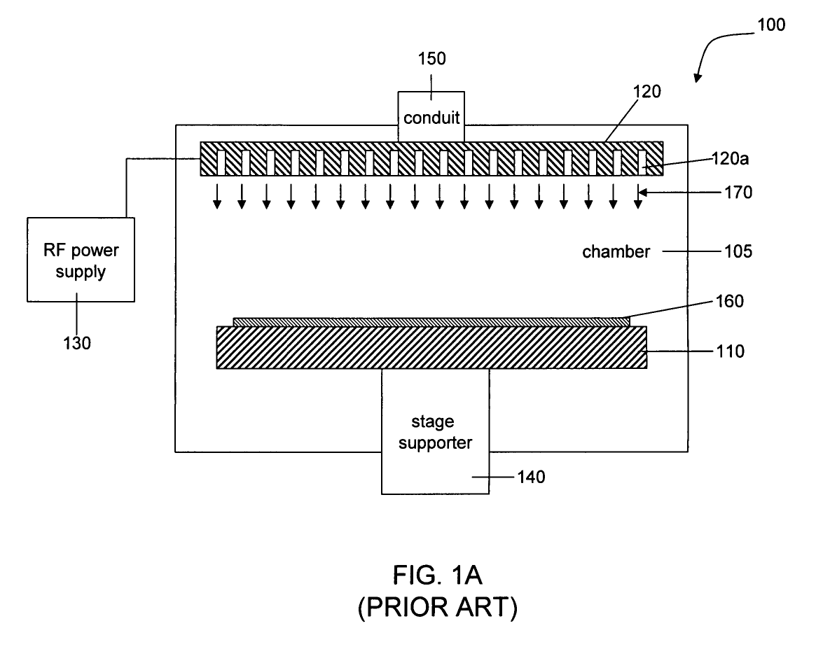

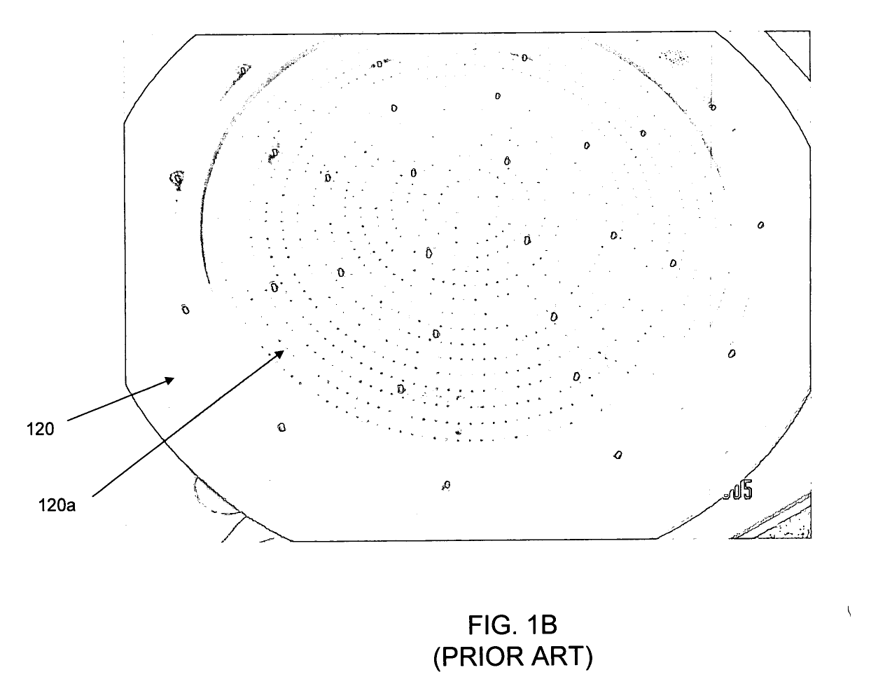

### DESCRIPTION OF THE PREFERRED EMBODIMENT

This description of the exemplary embodiments is intended to be read in connection with the accompanying drawings, which are to be considered part of the entire written description. In the description, relative terms such as “lower,” “upper,” “horizontal,” “vertical,” “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation.

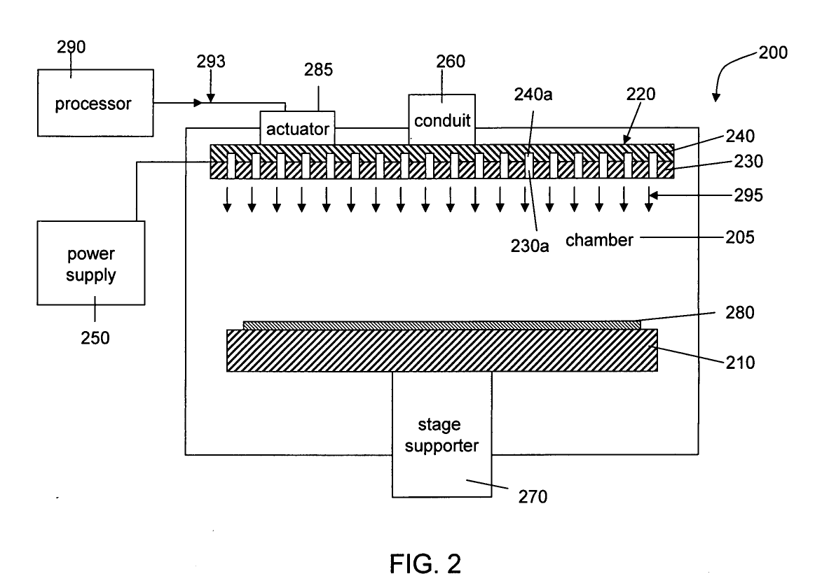

FIG. 2 is a schematic cross-sectional view showing an exemplary processing apparatus 200.

In FIG. 2, the processing apparatus 200 comprises a chamber 205, a stage 210, a gas distribution apparatus 220, a power supply 250, a conduit 260, a stage supporter 270, an actuator 285 and a processor 290. The stage 210 is disposed within the chamber 205. In some embodiments, the stage 210 is disposed on the chamber 205 so that a portion of the stage 210 is outside the chamber 205. In this embodiment, the stage supporter 270 may not be needed. The gas distribution apparatus 220 may be disposed within or on the chamber 205. A substrate 280 is disposed on the stage 210. The gas distribution apparatus 220 is disposed over the stage 210. The gas distribution apparatus 220 comprises a first plate 230 and a second plate 240. The first plate 230 comprises a plurality of first openings 230a. The second plate 240 comprises a plurality of second openings 240a. The second plate 240 is disposed over the first plate 230. The power supply 250 is coupled to the gas distribution apparatus 220. The power supply 250 can be coupled to the first plate 230, the second plate 240 or both of them, for example. The gas distribution conduit 260 is connected to the gas distribution apparatus 220. The stage supporter 270 is connected to the stage 210. The processor 290 is coupled to the actuator 285, as described in more detail below to move the plates 230 and 240 relative to each other. For example, the actuator 285 can be coupled to the first plate 230, the second plate 240 or both of them.

The chamber 205 can be an etch apparatus, chemical vapor deposition (CVD) chamber, physical vapor deposition (PVD) chamber, atomic layer deposition (ALD) chamber, remote plasma enhanced chemical vapor deposition (RPECVD) chamber, liquid source misted chemical deposition (LSMCD) chamber, furnace chamber, single wafer furnace chamber or other chamber in which chemical, gas or plasma is provided (collectively, “Semiconductor Processing Chamber”).

The substrate 280 can be, for example, a silicon substrate, a III-V compound substrate, a glass substrate, a liquid crystal display (LCD) substrate, a printed circuit board (PCB) or any other substrate similar thereto. In some embodiments, the substrate 280 can be a blank substrate or comprise a variety of integrated devices or circuits, or layers for forming such, (not shown) thereon, for example.

The conduit 260 is adapted to deliver a gas 295 to the gas distribution apparatus 220 for introduction into the chamber 205 by way of the openings 230a and 240a. The stage 210 is adapted to accommodate and hold the substrate 280. The stage 210 may comprise an electrostatic chuck, vacuum system, clamp or other apparatus that is able to keep the substrate 280 substantially on the stage 210. In some embodiments, the stage 210 also comprises a bottom electrode coupled to a power supply (not shown) so as to enhance plasma within the chamber 205. The stage supporter 270 is connected to and supports the stage 210 while a process is executed. In some embodiments, the stage supporter 270 comprises a conduit (not shown) connected to an exhaust pump (not shown) to exhaust gases or plasmas within the chamber 205. The gas 295 can be, for example, a pure chemical gas, a mixed chemical gas, a mist or moisture of chemical, an ionized gas, liquid, or other type of chemical. The gas 295 is provided in the chamber 205 by way of the openings 230a and 240a.

The power supply 250 can be, for example, a radio frequency (RF) power supply or other power supply that is adapted to provide a high voltage sufficient to ionize the gas 295 provided from the gas distribution apparatus 220 and to generate plasma in the chamber 205, as those in the art will understand. In some embodiments, the processing apparatus 200 is a single wafer furnace apparatus. For such embodiments, the power supply 250 can be eliminated, because generation of plasma is not required. One skilled in the art is readily able to select the chamber 205, the stage 210, the gas distribution apparatus 220, the power supply 250, the conduit 260 and/or the stage supporter 270 to provide a desired processing apparatus 200.

In a preferred embodiment, the processor 290 is coupled to the actuator 285 to control the relative orientation of the plates 230 and 240 relative to one another. The actuator 285 is coupled to the gas distribution apparatus 220. The actuator 285 can be, for example, a motor driven device for moving the plates relative to one another. A multitude of possible configurations are envisioned for accomplishing movement of the plates 230 and 240 relative to one another. In one preferred embodiment where the plates 230 and 240 are circular, the actuator 285 comprises a motor (not shown) that drives a shaft coupled to one of the plates 230 and 240. In response to a control signal 293 from the processor 290, the motor drives the shaft a predetermined angular displacement (i.e., a predetermined number of degrees) to change the orientation of the plates 230 and 240 relative to one another. In an alternative embodiment, no processor or motor are provided and the plates 230 and 240 can be reoriented manually with respect to one another and in accordance with predetermined guidelines for a desired gas distribution.

The actuator 285 is coupled to the first plate 230, the second plate 240 or both, for example. In some embodiments, more than one actuator 285 is provided. The actuator 285 may be located at various locations and either partially or wholly within or outside of the chamber 205. One skilled in the art can readily select the number, type and location of the actuator 285 to perform the dual orientation function.

As noted above, the processor 290 is coupled to the actuator 285. The processor 290 sends the control signal 293 to the actuator 285 to control a relative orientation of the first plate 230 and the second plate 240 so as to control the overlaps of the first openings 230a and the second openings 240a according to a predetermined recipe. The predetermined recipe tends to form a desired gas distribution pattern within the chamber 205. The recipe can be, in its basic form a correlation between a desired gas distribution and an angular, horizontal, vertical or other position of a shaft or other means that is coupled to the plate or plates to provide movement thereof. The gas distribution pattern is provided by controlling the dimensions of the overlaps of the first openings 230a and the second openings 240a. The processor 290 can be, for example, a central processing unit (CPU), a microprocessor, a programmable logic control unit, a computer or other device or system that is adapted to control the respective movement between the first plate 230 and the second plate 240 and that has access to recipe storage.

FIGS. 3A and 3B are top plan, schematic drawings of exemplary plates according to a first embodiment.

In FIGS. 3A and 3B, the first plate 230 comprises the first openings 230a and the second plate 240 comprises the second openings 240a. The first plate 230 can be, but need not necessarily be, for example, round, oval, rectangular, square or other desired shape corresponding to the shape of the substrate 280 to be processed in the chamber 205. The second plate 240 can be, but need not necessarily be, for example, round, oval, rectangular, square or other desired shape corresponding to the shape of the substrate 280 to be processed in the chamber 205. For example, round or oval plates 230 and 240 are adapted to process the substrate 280, which is a semiconductor wafer. Rectangular or square plates 230 and 240 are adapted to process the substrate 280, which is a liquid crystal display (LCD) substrate. In some embodiments, the correspondence of the shapes of the first plate 230 and the second plate 240 to the shape of the substrate 280 is not required. One skilled in the art can readily select the shapes of the first plate 230 and the second plate 240 based upon the substrate 280 and/or desired gas distribution pattern. In some embodiments, the gas distribution apparatus 220 is disposed within a shower head apparatus. In other embodiments, the first plate 230 is the shower head and the second plate 240 is disposed within or over the shower head, i.e., the first plate 230. One skilled in the art can readily select two plates or one shower head and one plate to form a desired gas distribution apparatus 220.

The second plate 240 is movable with respect to the first plate 230. For example, the movement between the first plate 230 and the second plate 240 may be a rotation, a horizontal movement, a vertical movement and/or other movement having a specified direction or angle. The respective movement between the first plate 230 and the second plate 240 can be created by fixing one of the two plates and moving the other plate, by moving both of the plates in opposite directions, or by moving both of the plates in the same directions but one of them moving faster or further than the other. In one embodiment, the first plate 230 and the second plate 240 are round disks and co-axial. In some embodiments, the first plate 230 is substantially fixed relative to the chamber 205 or other apparatus that is substantially fixed relative to the chamber 205. The second plate 240 is disposed over the first plate 230 and rotates with respect to the first plate 230 along the axis through the center (labeled “C” in FIG. 3B) of the disk, which is perpendicular to the second plate 240, in either or both of the clockwise or counter-clockwise direction.

The first openings 230a and the second openings 240a are configured on the first plate 230 and the second plate 240, respectively, along radial directions, along horizontal directions, along vertical directions, along directions with a specified angle, randomly or in other distribution pattern. The spaces between any two neighboring openings can be, for example, constant, uniformly increased or decreased or random. In some embodiments, the openings 230a and 240a are disposed in groups at concentric locations radially displaced from the center of the plates 230 and 240, respectively, with a constant space between two neighboring openings along any given radius line. One skilled in the art can readily select a desired distribution pattern and spaces of the openings 230a and 240a on the plates 230 and 240, respectively, based on a desired gas distribution.

In some embodiments, each of the first openings 230a corresponds to one of the second openings 240a. In other embodiments, the one-to-one corresponding design is not required, if a desired gas distribution provided by the gas distribution apparatus 220 can be achieved. The plates 230 and 240 shown in FIGS. 3A and 3B are merely exemplary embodiments. The present invention, however, is not limited thereto. In some embodiments, more or less openings 230a and 240a can be configured on the first plate 230 and the second plate 240, respectively. In addition, various shapes or distributions of the openings 230a and 240a can be formed based on the description set forth herein.

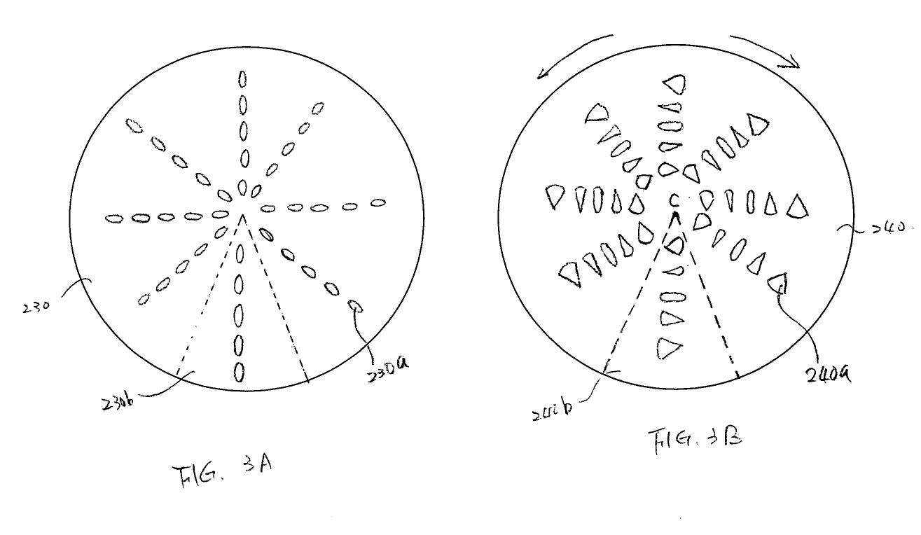

FIGS. 4A and 4B are enlarged schematic partial views of the plates 230 and 240 of FIGS. 3A and 3B, respectively. Specifically, FIGS. 4A and 4B illustrate portions 230b and 240b of FIGS. 3A and 3B, respectively.

In FIG. 4A, the first openings 230a are shown in the partial section 230b of the first plate 230. In some embodiments, the first openings 230a have substantially the same shape and dimensions. In embodiments, the first openings 230a have a symmetric shape such as oval, round, square, rectangular or other symmetric shapes. It is not required that the first openings 230a have the same shape and dimensions, if the first openings 230a cooperating with the second openings 240a can achieve a desired gas distribution. In one embodiment, the first openings 230a having oval shapes having a ratio of the short axis “a2” to the long axis “a1” from about 1:1.5 to about 1:2. In the illustrated embodiment, the long axis “a2” is oriented along a radius of the first plate 230. In some embodiments, the short axis “a2” of the oval shape openings 230a is from about 0.02 mm to about 2.0 mm. For example, if the first openings 230a are round, the lengths of the axes “a1” and “a2” can be about 2.0 mm. If the first openings 230a are oval and have the a1/a2 ratio of about 2/1, the short axis “a2” can be about 2.0 mm, and the long axis “a1” can be about 4.0 mm.

In FIG. 4B, the second openings 240a are shown in the partial section 240b of the second plate 240. In some embodiments, some or all of the second openings 240a have shapes whose one-half side area is larger than the other half-side area. Some of all of the second openings may have a one-half side area substantially equal to the other half side area. Referring to FIG. 4B, the half area 240a1 of the second opening 240a is larger than the other half area 240a2 of the second opening 240a, for example. The half area 240a3 of the second opening 240a is substantially equal to the other half area 240a4 of the second opening 240a. The shape of the second openings 240a can be, for example, an oblate with a tapered end, triangular, trapezoidal, oval, square, round, rectangular or other shape which may cooperate with the first openings 230a to form a desired gas distribution pattern. The second openings 240a may have substantially the same or different shapes and dimensions. In some embodiments, some of the second openings 240a of the second plate 240 have different shapes, dimensions and orientations. For example, the second openings 240a comprises oblate openings with different degree tapered ends and oval openings as shown in FIG. 4B. The shapes of the second openings 240a may be asymmetric or substantially symmetric, for example. In some embodiments, the long axis “a3” of an oblate shaped second opening 240a is larger than the short axis “a1” of the first opening 230a by about 10% or more. One skilled in the art can readily select the shapes and dimensions of the first openings 230a and the second openings 240a based on a desired gas distribution.

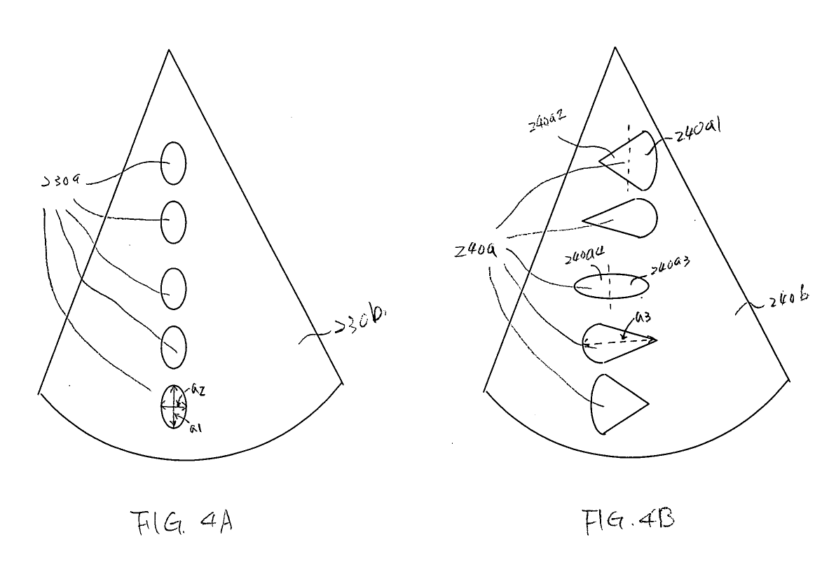

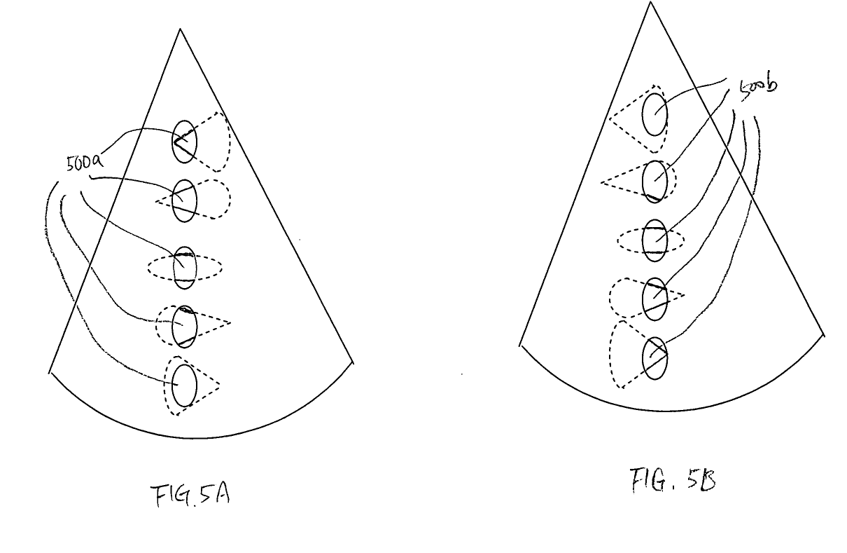

FIGS. 5A and 5B are schematic drawings showing overlaps of the partial plates of FIGS. 4A and 4B in two different orientations.

FIG. 5A shows overlaps of the first openings 230a and the second opening 240a in a first orientation of the second plate 240 with respect to the first plate 230. Due to the overlaps of the first openings 230a and the second opening 240a, portions of the first openings 230a are shielded by the second openings 240a so as to form the third openings 500a. In some embodiments, the third openings 500a may have substantially the same or different areas. For example, to obtain a uniform gas distribution in the chamber 205 of FIG. 2 at this orientation of plates 230 and 240, the third openings 500a have substantially the same area. In some embodiments, the third openings 500a may have different areas in order to form a desired gas distribution. Referring to FIG. 5A, the area of the third openings 500a gradually increase along the radial directions of the plates 230 and 240 toward the periphery (i.e., outer edge) of the plates 230 and 240. Because the areas of the third openings 500a determine the amount of the gas 295 permitted to be introduced into regions of the chamber 205 from the conduit 260 shown in FIG. 2, the gas distribution is controlled by the gas distribution apparatus 220, which comprises the first plate 230 and the second plate 240.

FIG. 5B shows overlaps of the first openings 230a and the second opening 240a after the rotation of the second plate 240 with respect to the first plate 230 to a second orientation. At least one of the openings 500b has an area different than its corresponding opening 500a in the new plate orientation, and in this embodiment, four of five openings 500b have different areas, either larger or smaller. Due to the overlaps of the first openings 230a and the second opening 240a, portions of the first openings 230a are shielded by the second openings 240a so as to form the third openings 500b. The third openings 500b may have substantially the same or different areas. Referring to FIG. 5B, the areas of the third openings 500b gradually decrease along the radial directions of the plates 230 and 240 toward the periphery of the plates 230a and 240a. Because the areas of the third openings 500b determine the amount of the gas 295 provided from the conduit 260 shown in FIG. 2 into the chamber 205, the gas distribution thus can be controlled by the gas distribution apparatus 220, which comprises the first plate 230 and the second plate 240.

In some embodiments, the first plate 230 comprises the second opening 240aand the second plate 240 comprises the first openings 230a. Because the respective movement of the first plate 230 and the second plate 240 still form the third openings 500a or 500b set forth above, the desired gas distributions can be achieved.

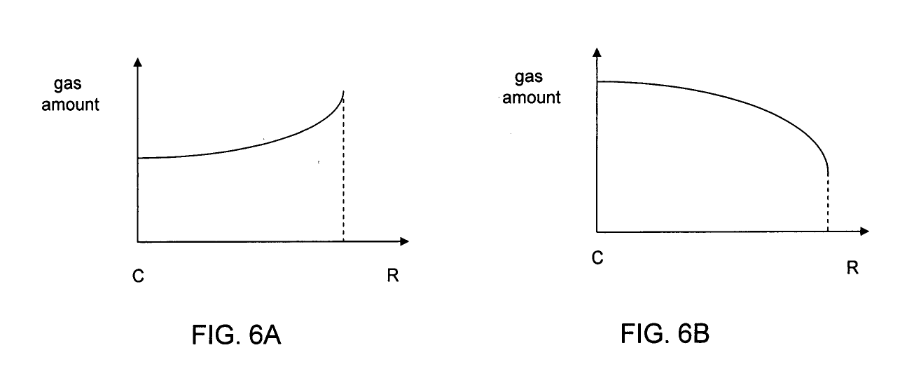

FIGS. 6A and 6B are schematic drawings showing exemplary gas distributions along a radial direction of a gas distribution apparatus. Specifically, FIG. 6A shows the gas distribution curve corresponding to the third openings 500a of FIG. 5A, i.e., at a first orientation of the plates 230 and 240 of FIGS. 3A and 3B. Referring to FIG. 5A, the areas of the third openings 500a gradually increase along the radial direction. The gas amount thus gradually increases from the center to the edge of the gas distribution apparatus 220 shown in FIG. 2. FIG. 6B shows the gas distribution curve corresponding to the third openings 500b of FIG. 5B, and thus at a second orientation of the plates 230 and 240 of FIGS. 3A and 3B. Because the dimensions of the third openings 500a gradually decrease along the radial direction, the gas amount gradually decreases from the center to the edge of the gas distribution apparatus.

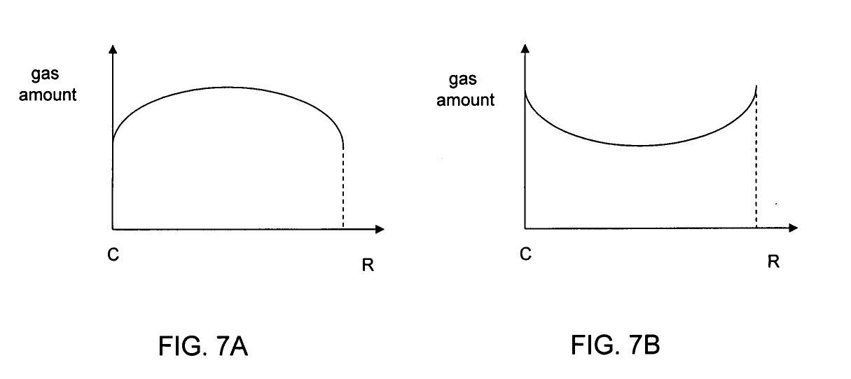

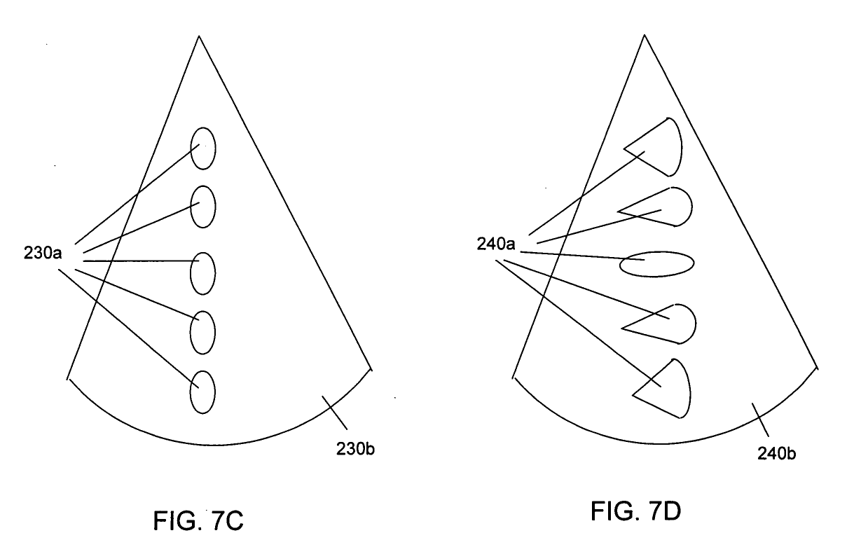

FIGS. 7A and 7B are schematic drawings showing other exemplary gas distributions along a radial direction of a gas distribution apparatus. FIGS. 7C and 7D are enlarged schematic drawings of portions of another embodiment of exemplary plates for providing the gas distribution of FIGS. 7A and 7B. Different orientations of the plates 230b and 240b of FIGS. 7C and 7D provide the gas distributions patterns of FIGS. 7A and 7B.

FIG. 7A shows that the gas amount gradually increases from the radial center to the radial middle of the gas distribution apparatus 220, and then gradually decreases from the radial middle to the edge of the gas distribution apparatus 220. This gas amount distribution pattern can be obtained by forming the third openings 500a or 500b having larger areas at the radial middle of the gas distribution apparatus 220. The gas distribution pattern can be achieved by, for example, using the first plate 230 in cooperation with the second plate 240 having the openings 240a with an oblate shape with a tapered end in the same direction as shown in FIG. 7C.

FIG. 7B shows that the gas amount gradually decreases from the radial center to the radial middle of the gas distribution apparatus 220, and then gradually increases from the radial middle to the edge of the gas distribution apparatus 220. Such gas amount distribution pattern can be obtained by forming the third openings 500a or 500b having smaller areas at the middle of the gas distribution apparatus 220. The gas distribution pattern can be achieved, for example, by rotating the second plate 240 having the second openings 240a shown in FIG. 7D in an opposite direction than the orientation used to achieve the distribution of FIG. 7A. It should be understood that FIGS. 6A-6B and 7A-7B are mere exemplary gas distributions according to the exemplary embodiments of the gas distribution apparatus 220 set forth above in connection to FIGS. 2-5 and 7C-7D. The present invention, however, is not limited thereto. One skilled in the art can readily select plates having different openings 230a and 240b, shapes and patterns to achieve the desired gas distributions.

Though the exemplary embodiment shown in FIGS. 2-5 illustrates two plates 230 and 240, the present invention is not limited thereto. For example, the gas distribution apparatus 220 may comprise more than two plates. As long as the third openings 500a and 500b set forth above can be formed by the overlaps of the openings of these plates, more than two plates can be applied in the gas distribution apparatus 220.

As set forth above, the gas 295 from the conduit 260 is provided to the chamber 205 by way of the third openings 500a or 500b. The movement of the second plate 240 with respect to the first plate 230 can be performed before or while the gas 295 is provided to the chamber 205 by way of the third openings 500a or 500b to generate plasma, for example. In a preferred embodiment, the movement of the second plate 240 with respect to the first plate 230 is performed before the gas 295 is provided to the chamber 205 by way of the third openings 500a or 500b so that gas will not be flowed down on the substrate 280 before the desired distribution pattern is established. One skilled in the art can readily modify the process steps to achieve the desired cleanness and vacuum level.

Although the present invention has been described in terms of exemplary embodiments, it is not limited thereto. Rather, the appended claims should be constructed broadly to include other variants and embodiments of the invention which may be made by those skilled in the field of this art without departing from the scope and range of equivalents of the invention.

What is claimed is:

1. A gas distribution apparatus, comprising:
a first plate comprising a plurality of first openings; and
a second plate disposed in overlapping relation with the first plate, the second plate comprising a plurality of second openings, wherein overlaps of the first openings and the second openings form third openings, the third openings providing a first gas distribution pattern at a first orientation of the plates relative to one another and a second gas distribution pattern at a second orientation different than the first orientation.

2. The gas distribution apparatus of claim 1, wherein the first plate is rotationally movable with respect to the second plate to modify the gas distribution pattern provided by the third openings.

3. The gas distribution apparatus of claim 1, wherein the first openings and second openings are configured in a plurality of groups of radially spaced openings, and each of the first openings corresponds to one of the second openings.

4. The gas distribution apparatus of claim 1, wherein each of the first openings has substantially the same area and shape, the shape being symmetrical.

5. The gas distribution apparatus of claim 4, wherein the symmetric shape is oval, round, square or rectangular.

6. The gas distribution apparatus of claim 4, wherein a short axis and a long axis of the oval shape has a ratio from about 1:1.5 to 1:2, and dimensions of the short axis of the oval shape are from about 0.02 mm to about 2.0 mm.

7. The gas distribution apparatus of claim 4, wherein the second openings comprise at lest some openings having shapes whose one-half side area is larger than, or substantially equal to, the other-half side area.

8. The gas distribution apparatus of claim 7, wherein the shape of at least some of the second openings is an oblate with a tapered end, is triangular or is trapezoidal.

9. The gas distribution apparatus of claim 6, wherein the shape of at least some of the second openings is an oblate with a tapered end, and wherein a long axis of the oblate shape is larger than the short axis of the oval shape by about 10% or more, and areas of the third openings increase approaching a periphery of the plates in the first orientation and decrease in the second orientation.

10. The gas distribution apparatus of claim 1 further comprising a chamber having a stage therein, the stage being disposed under the first plate and the second plate.

11. The gas distribution apparatus of claim 10 further comprising a power supply coupled to at least one of the first and second plates.

12. The gas distribution apparatus of claim 1 further comprising:
at least one actuator coupled to at least one of the first and second plates; and
a processor coupled to the actuator, the processor providing a control signal corresponding to a predetermined recipe to the actuator to control the orientation of the first and second plates relative to one another.

13. The gas distribution apparatus of claim 1, wherein at least one of the third openings in the first orientation has an area different than the area of at least one third opening in the second orientation.

14. An apparatus, comprising:
a gas distribution apparatus comprising:
a first disk comprising a plurality of groups of radially spaced first openings having an oval shape; and
a second disk disposed in overlapping relation with the first disk, the second disk comprising a plurality of groups of radially spaced second openings, each group corresponding to a group from the first disk, at least some of the second openings having shapes whose one-half side area is larger than the other-half side area, wherein the first disk is rotationally movable with respect to the second disk, overlaps of the first and second openings forming third openings, the third openings providing a first gas distribution pattern at a first rotational orientation of the disks relative to one another and a second gas distribution pattern at a second rotational orientation different than the first orientation, areas of at least some of the third openings being different in the first orientation than the second orientation;
a chamber comprising a stage therein, the stage being disposed under the gas distribution apparatus;
a power supply coupled to the gas distribution apparatus;
at least one actuator coupled to the gas distribution apparatus; and
a processor incommunication with the actuator, the processor providing a control signal corresponding to a predetermined recipe to the actuator to control the orientation of the first and second disks relative to one another.

15. The apparatus of claim 14, wherein the first openings each have the same area.

16. The apparatus of claim 14, wherein the actuator comprises a motor.

17. A method of controlling a gas distribution apparatus, comprising steps of:
(a) orientating a first plate comprising a plurality of first openings with respective to a second plate comprising a plurality of second openings so that overlaps of the first openings and the second openings form third openings corresponding to a selected gas distribution pattern, the third openings providing a first gas distribution pattern at a first orientation of the plates relative to one another and a second gas distribution pattern at a second orientation different than the first orientation; and
(b) providing a gas by way of the third openings to a chamber.

18. The method of claim 17, wherein step (a) is performed prior to step (b).

19. The method of claim 17, wherein step (a) comprises rotating the plates relative to one another.

20. The method of claim 17, wherein the orientation step is responsive to a control signal.
